(19) United States
(12) Patent Application Publication
(10) Pub. No.: US 2005/0189620 A1
(43) Pub. Date: Sep. 1, 2005

(54) Manufacturing method for semiconductor device, and system to which semiconductor is applied

(76) Inventors: Takashi Sugino, Osaka (JP); Masaki Kusuhara, Tokyo (JP); Masaru Umeda, Tokyo (JP)

Correspondence Address: RANDALL J. KNUTH P.C., 4921 DESOTO DRIVE, FORT WAYNE, IN, 46815, US

(21) Appl. No.: 10/789,795

(22) Filed: Feb. 25, 2004

(30) Foreign Application Priority Data
Feb. 27, 2003 (JP) 2003-52050

(51) Int. Cl. H01L 29/12

(52) U.S. Cl. 257/613

(57) ABSTRACT

A high performance semiconductor device that can realize surface protection and surface inactivation and is fabricated using a film formation method and technique that enable improvement of high frequency characteristics, and an electronic device for a communication system including the semiconductor device, are provided. The semiconductor device is characterized in that a film having boron, carbon, and nitrogen as main components and to which sulfur is added serves as a surface protection film, and at least part of a surface is covered.

### DETAILED DESCRIPTION OF THE INVENTION

1. Background of the Invention

The present invention relates to an improvement in the performance of semiconductor devices by protection and inactivation of a semiconductor surface.

2. Prior Art

Field effect transistors (FETs) and hetero-junction bipolar transistors (HBTs) have been developed and put to practical uses as high frequency electronic devices. Surface levels are generated due to dangling bonds and oxidation in the exposed semiconductor surfaces between gates and drains or between sources and gates in FETS, and in the semiconductor surfaces at the ends of base regions in HBTs, inducing deterioration in the performance of the transistor. Increases in leak currents between gates and drains in FETS have been observed, and reductions in minority carriers due to surface recombination within the bases of HBTs have occurred. With regard to electronic devices formed by a III-V compound semiconductor with GaAs or InP as a base material, an increase in state density in the surface due to oxidation or the like has been particularly notable, and because this deteriorates the performance of the device, semiconductor surface inactivation processing techniques and surface protection film fabrication techniques have been developed to advance the fabrication of electronic devices. Although until now silicon oxide film and silicon nitride film have been used as semiconductor surface protection and inactivation films, for the even higher frequency operations being pursued for the future, increasing the intrinsic high frequency characteristics of elements by reducing stray capacitance and improving signal delay in the wiring of integrated circuits are indispensable. As a result, it is necessary to reduce the dielectric constant of the protective film and the insulating film between wiring layers used to date. Although the dielectric constants of silicon oxide film and silicon nitride film are known to be approximately k=4 and k=7 respectively, in the future the introduction of materials with even lower dielectric constants will be desirable. Also, a surface protecting film that can be applied to devices that use GaN as a base material, which have drawn attention as future high frequency power devices, is desired.

Establishing a surface protection technique and surface inactivation technique for III-V compound semiconductors and improving the performance of high frequency electronic devices are desired. The present invention was created in light of the above situation, and has as its object to provide a high performance semiconductor device that can realize surface protection and surface inactivation and is fabricated using a film forming method and technique of fabricating by adding sulfur (S) to a film (BCN film) that serves as a surface protection film in which boron, carbon, and nitrogen are the main components, enabling improvement of high frequency characteristics, and an electronic device for a communication system including the semiconductor device.

### DISCLOSURE OF THE INVENTION

The semiconductor device of the present invention for solving the above problems is characterized by having a coating that has boron, carbon and nitrogen as its main components and sulfur added thereto as a surface protection film, at least one part of the surface being coated. The fixed charge at the interface of the film and semiconductor can be reduced by adding sulfur, and the density of defective levels of the semiconductor surface can be reduced by the sulfur atoms. The result of depositing a BCN film to which sulfur has been added and a BCN film to which it has not been added on an n-type Si substrate to fabricate a metal/insulator/semiconductor structure, and measuring its capacity and voltage characteristics is shown in FIG. 1. Compared to the BCN film without addition, in the sulfur additive BCN film a reduction in flat band shift is clearly noticeable, and it can be easily understood that the BCN film characteristics and interface characteristics have been improved by adding sulfur.

Also, the semiconductor device of the present invention for achieving the above object is characterized in that the carbon composition ratio (atomic ratio) of the coating is 0.1 or more. A reduction of the dielectric constant is thereby reduced, water resistance is improved, and cracking and peeling of the film prevented.

Further, the semiconductor device of the present invention for achieving the above object is characterized by including oxygen in the above coating.

Moreover, the semiconductor device of the present invention for achieving the above object is characterized by having a multi-layer structure with a heterogeneous film attached to the above coating. By having a multi-layer structure, its stability as a protective film is improved.

Furthermore, the semiconductor device of the present invention for achieving the above object is characterized in that the heterogeneous film contains a different amount of structural elements to the above coating.

Further still, the semiconductor device of the present invention for achieving the above object is characterized in that the heterogeneous film is a film with the same main components as the above coating, without the addition of sulfur.

Even further, the semiconductor device of the present invention for achieving the above object is characterized in that the heterogeneous film is a film with silicon as the main component.

In addition, the semiconductor device of the present invention for achieving the above object is characterized by having a III-V compound semiconductor.

Also, the semiconductor device of the present invention for achieving the above object is characterized by being a field effect transistor, a bipolar transistor, or a diode.

Further, the fabrication method of the semiconductor device of the present invention for achieving the above object is characterized by disposing a film formation substrate in a plasma atmosphere containing nitrogen and supplying boron atoms, carbon atoms and sulfur atoms to the film formation substrate to form a boron carbon nitride film to which sulfur has been added.

The sulfur addition method can, for example, heat solid sulfur (400K) and carry it to a reactor with nitrogen gas. Also, introducing hydrogen sulfide (H₂S) is preferred for improving controllability.

The amount to which sulfur atoms are introduced into the film is approximately 10²⁰ cm³. It is thought that the effect may be exhibited by adding 10¹⁸ cm³ or more.

Also, the fabrication method of the semiconductor device of the present invention for achieving the above object is characterized by disposing the film formation substrate facing a boron nitride sputtered portion and supplying carbon atoms and sulfur atoms to the film formation substrate to form a boron carbon nitride film to which sulfur has been added.

Further, the fabrication method of the semiconductor device of the present invention for achieving the above object is characterized by disposing the film formation substrate facing a boron nitride and carbon sputtered portion and supplying sulfur atoms to the film formation substrate to form a boron carbon nitride film to which sulfur has been added.

Moreover, the fabrication method of the semiconductor device of the present invention for achieving the above object is characterized by disposing the film formation substrate facing a boron nitride laser abrasion and supplying plasma containing carbon atoms and sulfur atoms to the film formation substrate to form a boron carbon nitride film to which sulfur has been added.

Furthermore, the fabrication method of the semiconductor device of the present invention for achieving the above object is characterized by disposing the film formation substrate facing a boron nitride and carbon laser abrasion and supplying plasma containing sulfur atoms to the film formation substrate to form a boron carbon nitride film to which sulfur has been added.

Additionally, the communication system device of the present invention for achieving the above object has a semiconductor device fabricated according to the present invention.

### BRIEF DESCRIPTION OF THE DRAWINGS

FIG. 1 is a graph showing the volume to voltage characteristic of the present invention;

FIG. 2 is a cross sectional view of a semiconductor device according to a first embodiment of the present invention; and

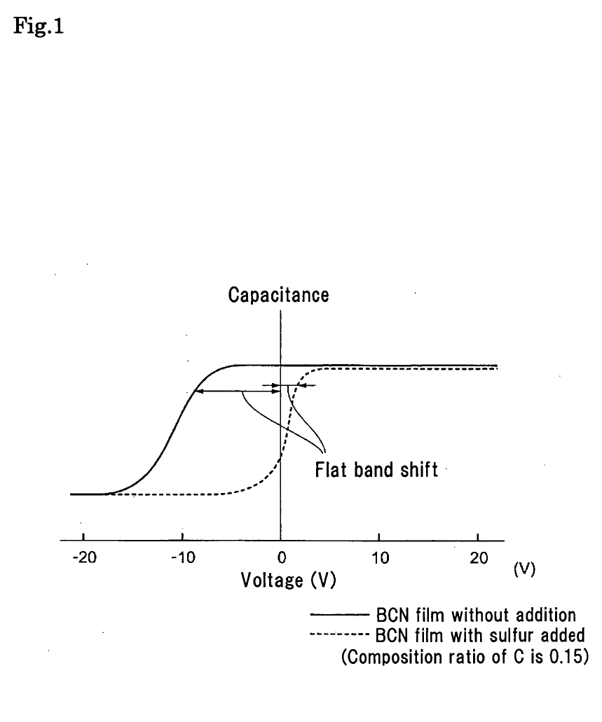

FIG. 3 is a cross sectional view of a semiconductor device according to a first embodiment of the present invention;
21: semi-insulating GaAs substrate
22: n-type GaAs activation layer
23: source electrode
24: drain electrode
25: gate electrode
26: surface protection film
26-1: first boron carbon nitride film
26-2: second boron carbon nitride film
31: n-GaAs substrate
32: n type GaAs collector layer
33: p type GaAs base layer
34: n type AlGaAs emitter layer
35: n type GaAs contact layer
36: emitter electrode
37: base electrode
38: collector electrode
39: surface protection film
39-0: semiconductor
39-1: first boron carbon nitride film
39-2: second boron carbon nitride film

### DETAILED DESCRIPTION OF THE PREFERRED EMBODIMENTS

The embodiments of the present invention will be explained in detail below using the drawings.

### Embodiment 1

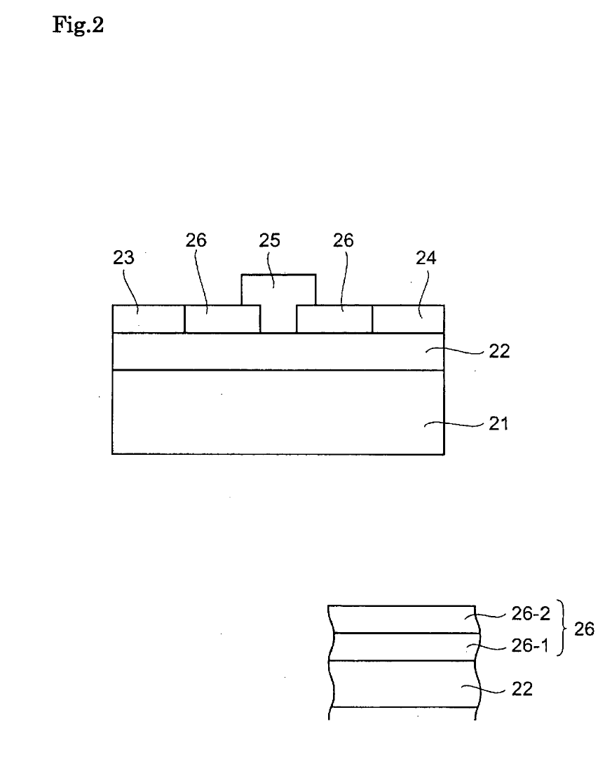

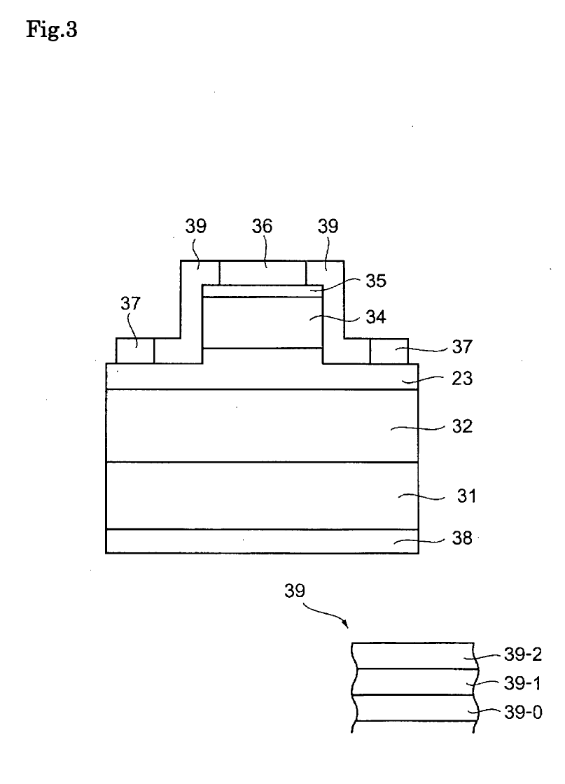

FIG. 2 is a schematic diagram showing a field effect transistor (FET) as a semiconductor device of a first embodiment of the present invention. A wafer formed by growing an n-type GaAs active layer 22 on a semi-insulating GaAs substrate 21 by metal organic chemical vapor deposition (MOCVD) is used. An ohmic junction is formed thereon, then a source electrode 23 and drain electrode 24 are formed. After element separation, the surface protection film 26 of the present invention is deposited on the GaAs active layer 22 between the source 23 and drain 24. Using a plasma CVD device, after making the sample temperature 300° C. and processing the surface with hydrogen plasma, a first boron carbon nitride film 26-1 is deposited to 100 nm using nitrogen, methane plasma and boron trichloride. At this time, sulfur atoms are supplied to the plasma. Subsequently, methane concentration is increased and a second boron carbon nitride film 26-2 is deposited to 200 nm. At this time the supply of sulfur atoms is stopped. A window is opened for forming a gate electrode 25 between the source 23 and drain 24 by photolithography, a Schottky junction formed, and a gate electrode 25 provided.

By fabricating a FET in this way, surface protection between source and gate and between gate and drain is achieved and stray capacitance is reduced to half or less that of a device using only a silicon oxide film or silicon nitride film. Also, an increase in the drain current can be realized.

Although a GaAs FET has been used in the present embodiment, a hetero FET, HEMT, or similar type of FET can be used. Also, the present invention is not limited to the GaAs FET used in the present embodiment, and can be similarly used with an FET formed with another III-V compound semiconductor. Further, with regard to the structure of the surface protection film, a silicon nitride film or silicon oxide film can be used as the film formed on the sulfur additive boron carbon nitride film of the present invention.

### Embodiment 2

FIG. 3 is a schematic diagram showing a hetero-junction bipolar transistor (HBT) as a semiconductor device of the second embodiment of the present invention. An n-type GaAs collector layer 32 is grown to 2 μm, a p-type GaAs base layer 33 to 2 nm, an n-type AlGaAsN emitter layer to 1 μm, and an n-type GaAs contact layer 35 to 50 nm on an n-type GaAs substrate 31 by metal organic chemical vapor deposition (MOCVD). After element separation, the contact layer 35 and emitter layer 34 are removed, leaving an emitter portion, the base layer 33 is exposed, and the surface protection film 39 of the present invention is deposited. After making the sample temperature 300° C. inside a plasma CVD device and processing the surface with hydrogen plasma, a first boron carbon nitride film 39-1 is deposited to 100 nm using nitrogen, methane plasma and boron trichloride. At this time, deposition is performed by supplying sulfur atoms to the plasma. Subsequently, the methane concentration thereon is increased and a second boron carbon nitride film 39-2 is deposited to 300 nm. At this time the supply of sulfur atoms is stopped. An emitter electrode 36 portion is etched in the surface protection film 39 by photolithography to form the emitter electrode 36. Similarly, a base electrode 37 portion is etched in the surface protection film 39 by photolithography and a base electrode 37 formed. Finally, a collector electrode 38 is formed in the surface of the substrate to conclude the process.

By fabricating an HBT in this way, compared to a device in which only silicon oxide or silicon nitride is used for surface protection of the base layer 33, the emitter grounding current amplification factor is increased by 50% or more.

Although first and second boron carbon nitride films have been used as surface protection films in the present embodiment, a silicon nitride film or silicon oxide film can be used as the film formed on the sulfur additive boron carbon nitride film which is the first boron carbon nitride film of the present invention. Also, the present invention is not limited to an HBT having the GaAs/AlGaAs layer structure used in the present embodiment, and can be similarly applied to HBTs formed by other III-V compound semiconductors.

### EFFECTS OF THE INVENTION

The present invention provides a method of further reducing surface defect densities by fabricating a sulfur additive boron carbon nitride film having a low dielectric constant in the surface of a semiconductor, can be applied to fabricating semiconductor elements such as FETs and HBTs, and is effective in increasing the performance of high frequency electronic elements.

Also, semiconductor elements fabricated using the techniques of the present invention can be provided as key devices for high performance information processing devices, communication system devices, and the like.

1. A semiconductor device having a surface, comprising:
a coating disposed on said semiconductor device surface to cover at least a portion thereof, said coating including boron, carbon, nitrogen and sulfur.

2. The semiconductor device of claim 1, wherein a carbon composition ratio (atomic ratio) of the coating is at least 0.1.

3. The semiconductor device of claim 1, wherein said coating includes oxygen.

4. The semiconductor device of claim 1, further includes a multi-layer structure with a heterogeneous film attached to the coating.

5. The semiconductor device of claim 4, wherein said heterogeneous film contains an amount of structural elements different than the coating.

6. The semiconductor device of claim 4, wherein said heterogeneous film is a film with main components identical to the coating, without sulfur being added thereto.

7. The semiconductor device of claim 4, wherein said heterogeneous film is a film with silicon as a main component.

8. The semiconductor device of claim 1, further includes a III-V compound semiconductor.

9. The semiconductor device of claim 8, wherein said semiconductor is a field effect transistor.

10. The semiconductor device of claim 8, wherein said semiconductor is a bipolar transistor.

11. The semiconductor device of claim 8, wherein said semiconductor is a diode.

12. A semiconductor device fabrication method, said method comprising the steps of:
disposing a film formation substrate in a plasma atmosphere containing nitrogen; and
supplying boron atoms, carbon atoms and sulfur atoms to the film formation substrate to thereby form a boron carbon nitride film having sulfur as an additive thereto.

13. A semiconductor device fabrication method, said method comprising the steps of:
disposing a film formation substrate facing a boron nitride sputter portion; and
supplying carbon atoms and sulfur atoms to the film formation substrate to thereby form a boron carbon nitride film having sulfur as an additive thereto.

14. A semiconductor device fabrication method, said method comprising the steps of:
disposing a film formation substrate facing a boron nitride and carbon sputter portion; and
supplying sulfur atoms to the film formation substrate to thereby form a boron carbon nitride film having sulfur as an additive thereto.

15. A semiconductor device fabrication method, said method comprising the steps of:
disposing a film formation substrate facing a boron nitride laser abrasion; and
supplying plasma containing carbon atoms and sulfur atoms to the film formation substrate to thereby form a boron carbon nitride film having sulfur as an additive thereto.

16. A semiconductor device fabrication method, said method comprising the steps of:
disposing a film formation substrate facing a boron nitride and carbon laser abrasion; and
supplying plasma containing sulfur atoms to the film formation substrate to thereby form a boron carbon nitride film having sulfur as an additive thereto.

17. The semiconductor device fabrication method of any one of claims 12 to 16, characterized in that the semiconductor is a field effect transistor.

18. The semiconductor device fabrication method of any one of claims 12 to 16, characterized in that the semiconductor is a bipolar transistor.

19. The semiconductor device fabrication method of any one of claims 12 to 16, characterized in that the semiconductor is a diode.

20. A communication system device, comprising:
a semiconductor device having a surface; and
a coating disposed on said semiconductor device surface to cover at least a portion thereof, said coating including boron, carbon, nitrogen and sulfur.
